(19) United States
(12) Patent Application Publication
(10) Pub. No.: US 2014/0327510 A1
(43) Pub. Date: Nov. 6, 2014

(54) ELECTRONIC DEVICE HAVING ASYMMETRICAL THROUGH GLASS VIAS

(71) Applicant: QUALCOMM INCORPORATED, San Diego, CA (US)

(72) Inventors: Daeik D. Kim, San Diego, CA (US); David F. Berdy, West Lafayette, IN (US); Chengjie Zuo, Santee, CA (US); Mario Francisco Velez, San Diego, CA (US); Changhan Yun, San Diego, CA (US); Robert P. Mikulka, Oceanside, CA (US); Jonghae Kim, San Diego, CA (US); Je-Hsiung Lan, San Diego, CA (US)

(73) Assignee: QUALCOMM Incorporated, San Diego, CA (US)

(21) Appl. No.: 13/887,788

(22) Filed: May 6, 2013

(51) Int. Cl. H05K 9/00; H05K 3/10; H05K 3/00; H01F 5/00; H05K 1/11

(52) U.S. Cl. CPC H05K 9/002; H01F 5/003; H05K 1/115; H05K 3/0017; H05K 3/107
USPC 336/200; 174/262; 174/350; 716/118; 156/345.24; 216/18

(57) ABSTRACT

An electronic device includes a structure. The structure includes a first set of through glass vias (TGVs) and a second set of TGVs. The first set of TGVs includes a first via and the second set of TGVs includes a second via. The first via has a different cross-sectional shape than the second via.

### I. FIELD

The present disclosure is generally related to electronic devices.

### II. DESCRIPTION OF RELATED ART

Advances in technology have resulted in smaller and more powerful computing devices. For example, there currently exist a variety of portable personal computing devices, including wireless computing devices, such as portable wireless telephones, personal digital assistants (PDAs), and paging devices that are small, lightweight, and easily carried by users. More specifically, portable wireless telephones, such as cellular telephones and internet protocol (IP) telephones, can communicate voice and data packets over wireless networks. Further, many such wireless telephones include other types of devices that are incorporated therein. For example, a wireless telephone can also include a digital still camera, a digital video camera, a digital recorder, and an audio file player. Also, such wireless telephones can process executable instructions, including software applications, such as a web browser application, that can be used to access the Internet. As such, these wireless telephones can include significant computing capabilities.

A substrate (e.g., a silicon substrate or a glass substrate) may be a foundation upon which a semiconductor device such as semiconductor devices used in electronic devices (e.g., wireless devices or computing devices) may be fabricated. A silicon substrate is typically selected for semiconductor device fabrication. A glass substrate can be used as an alternative to a silicon substrate. A glass substrate may be less expensive than a silicon substrate. Also, in applications involving radio frequency signals, a glass substrate may cause reduced signal attenuation as compared to a silicon substrate. A through glass via (TGV) can be used within a glass substrate to create three dimensional stacked devices. A TGV typically has a circular cross-sectional shape. When a TGV that has a regular circular cross-sectional shape is used in a non-straight solenoid inductor, the inductor is susceptible to interference from electromagnetic signals generated by nearby electronic devices as sparse TGV allows electromagnetic coupling. At the same time, the inductor may have a less optimal resistance and a reduced efficiency.

### III. SUMMARY

An inductor having circular through glass vias (TGVs) may be susceptible to interference from nearby electromagnetic signals (e.g., magnetic fields). The interference from the nearby electromagnetic signals may reduce efficiency of the inductor. Systems and methods described herein may advantageously be used to form an inductor that is less susceptible to interference from nearby electromagnetic signals. Also, the inductor may have an increased efficiency (e.g., a higher quality (Q) factor).

For example, an inductor (e.g., a toroidal inductor) may be formed using a glass substrate. The inductor may have an inner region and an outer region. A region of the glass substrate between the inner region and the outer region may correspond to a core of the inductor. The inductor may include asymmetrical TGVs. For example, the inner region may include at least one TGV having a circular cross section, and the outer region may include at least one TGV having a non-circular (e.g., oval, rectangular, elliptical, concave, etc.) cross section. The TGV having the non-circular cross section may have a greater width than the TGV having the circular cross section. Each TGV having a non-circular cross section may shield more electromagnetic signals from nearby electronic devices as compared to a TGV having a circular cross-section.

In a toroidal inductor, a magnetic field generated by the toroidal inductor may be substantially contained within a cross section core of the toroidal inductor. The magnetic field affects an efficiency (e.g., a Q factor) of the toroidal inductor. When the magnetic field is affected by nearby electromagnetic signals, the efficiency of the toroidal inductor is reduced (e.g., a lower Q factor). By using TGVs having a non-circular cross section in the outer region, space between each of the TGVs in the outer region is reduced as compared to TGVs having a circular cross section. Accordingly, less nearby electromagnetic signals may pass through the outer region of the toroidal inductor. Thus, the toroidal inductor using TGVs having a non-circular cross section in the outer region may be less susceptible to nearby electromagnetic signals.

In a particular embodiment, an electronic device comprises a structure. The structure comprises a first set of through glass vias (TGVs) and a second set of TGVs. The first set of TGVs comprises a first via and the second set of TGVs comprises a second via. The first via has a different cross-sectional shape than the second via. In a particular embodiment, the structure is an inductor structure.

In a particular embodiment, a method of making a TGV comprises patterning a through glass via (TGV) hard mask on a surface of a glass substrate to create a cavity having a non-circular cross section. The method also comprises etching a portion of the glass substrate through the cavity. The method further comprises applying a conductive material in the etched portion to form a TGV having the non-circular cross section. The TGV is integrated in a device that comprises a structure. The structure comprises a first set of TGVs and a second set of TGVs. The first set of TGVs comprises a first via and the second set of TGVs comprises a second via. The first via has a different cross-sectional shape than the second via.

One particular advantage provided by at least one of the disclosed embodiments is an ability to reduce interference from nearby electromagnetic signals to increase an efficiency of an inductor (e.g., increasing a Q factor of the inductor). Another particular advantage provided by at least one of the disclosed embodiments is that magnetic flux generated by a toroidal inductor is confined within the toroidal inductor to reduce interference from nearby electromagnetic signals. Other aspects, advantages, and features of the present disclosure will become apparent after review of the entire application, including the following sections: Brief Description of the Drawings, Detailed Description, and the Claims.

### IV. BRIEF DESCRIPTION OF THE DRAWINGS

FIG. 1 is a diagram that illustrates a particular embodiment of an electronic device that includes a through glass via (TGV) having a non-circular cross section;

FIG. 2 is a diagram that illustrates another particular embodiment of an electronic device that includes a TGV having a non-circular cross section;

FIG. 3 is a flowchart that illustrates a particular embodiment of a method to manufacture a TGV having a non-circular cross section;

FIG. 4 is a flowchart that illustrates another particular embodiment of a method to manufacture a TGV having a non-circular cross section;

FIG. 5 is a diagram that illustrates a communication device that includes a TGV having a non-circular cross section; and

FIG. 6 is a data flow diagram that illustrates a particular embodiment of a process to manufacture electronic devices that include a TGV having a non-circular cross section.

### V. DETAILED DESCRIPTION

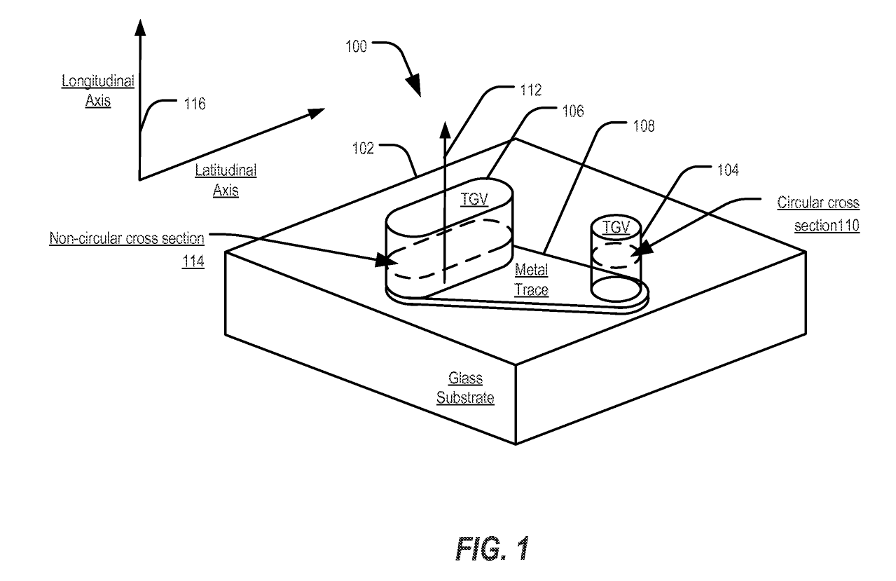

FIG. 1 illustrates a particular embodiment of an electronic device 100 that includes a through glass via (TGV) having a non-circular cross section. The electronic device 100 may be an inductor. The electronic device 100 may include a glass substrate 102, a first TGV 104, a second TGV 106, and a metal trace 108 that connects the first TGV 104 to the second TGV 106. The electronic device 100 may include asymmetrical TGVs. TGVs of the electronic device 100 may have different cross-sectional shapes. For example, the first TGV 104 may have a circular cross section 110, and the second TGV 106 may have a non-circular cross section 114. The first TGV 104 may have a different cross-sectional shape than the second TGV 106.

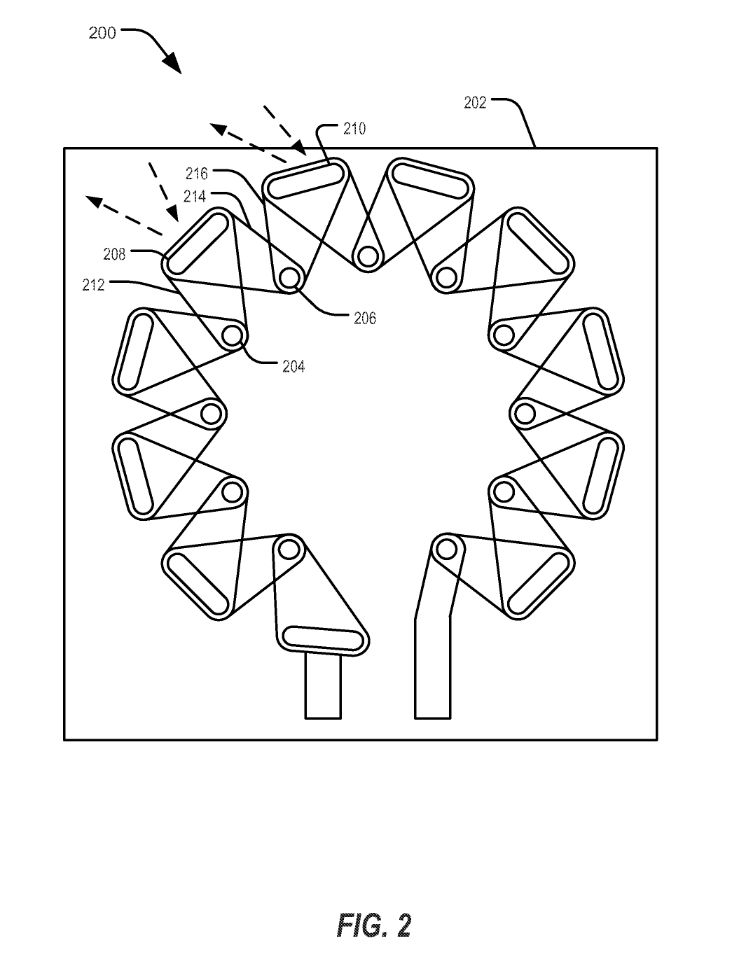

The non-circular cross section 114 may have a greater width than the circular cross section 110. In a particular embodiment, the non-circular cross section 114 may have an oval shape. In another particular embodiment, the non-circular cross section 114 may have a rectangular shape. In another particular embodiment, the non-circular cross section 114 may have an elliptical shape. In another particular embodiment, the non-circular cross section 114 may have a concave shape. The non-circular cross section 114 is perpendicular to a major axis 112 of the second TGV 106. The major axis 112 may be parallel to a longitudinal axis 116 (and perpendicular to a surface of the glass substrate 102 as shown). The non-circular cross section 114 has a greater width than the circular cross section 110. During operation, current may flow between the first TGV 104 and the second TGV 106 via the metal trace 108. When the second TGV 106 is located in an outer region of a toroidal inductor, the non-circular cross section 114 may enable the second TGV 106 to shield a greater amount of interference from nearby electromagnetic signals (e.g., magnetic fields) as compared to the first TGV 104. A toroidal inductor that includes a TGV having a non-circular cross section is described with reference to FIG. 2.

FIG. 2 is a diagram that illustrates another particular embodiment of an electronic device 200 that includes a TGV having a non-circular cross section. The electronic device 200 is a toroidal inductor. The electronic device 200 may include a glass substrate 202, a first set of TGVs, a second set of TGVs, and metal traces that connect the first set of TGVs to the second set of TGVs.

The electronic device 200 may include asymmetrical TGVs. For example, the first set of TGVs may include a first TGV 204 and a second TGV 206. The first set of TGVs may correspond to an inner region of the electronic device 200. While only two of the TGVs in the inner region of the toroidal inductor are described, the inner region includes many TGVs (see FIG. 2). The second set of TGVs may include a third TGV 208 and a fourth TGV 210. The second set of TGVs may correspond to an outer region of the electronic device 200. While only two of the TGVs in the outer region of the toroidal inductor are described, the outer region includes many TGVs (see FIG. 2). The first TGV 204 may be connected to the third TGV 208 via a first metal trace 212. The third TGV 208 may be connected to the second TGV 206 via a second metal trace 214. The second TGV 206 may be connected to the fourth TGV 210 via a third metal trace 216. The first metal trace 212 and the third metal trace 216 may be located on the top surface of the glass substrate 202. The second metal trace 214 may be located on the bottom surface of the glass substrate 202.

The first TGV 204 and the second TGV 206 may each have a circular cross sectional shape. The third TGV 208 and the fourth TGV 210 may each have a non-circular cross-sectional shape. During operation, current may flow from one TGV to another TGV via a metal trace (e.g., current may flow from the first TGV 204 to the third TGV 208 via the first metal trace 212). The non-circular cross sections of the third TGV 208 and the fourth TGV 210 enable the third TGV 208 and the fourth TGV 210 to have a greater width than the first TGV 204 and the second TGV 206. The third TGV 208 and the fourth TGV 210 may provide shielding from surrounding magnetic fields (as indicated by dotted arrows in FIG. 2). Such shielding of magnetic fields results in greater efficiency and a reduced resistance of the electronic device 200. A Q factor indicates inductor efficiency in storing energy. In a particular embodiment, the electronic device 200 has a quality (Q) factor of 66.3 at 2 GHz as compared to a Q factor of 62.4 of a toroidal inductor implemented using TGVs that have circular cross-sectional shapes. Thus, the electronic device 200 that includes TGVs with a non-circular cross section has an increased inductor efficiency.

Although the toroidal inductor 200 is illustrated in FIG. 2, it should be understood that other structures may include TGVs having non-circular cross sections (e.g., the third TGV 208 and the fourth TGV 210). For example, a half bent solenoid inductor may include TGVs having non-circular cross sections on an outer region of the half bent solenoid inductor and may include TGVs having circular cross sections on an inner region of the half bent solenoid inductor. As another example, an S-shaped inductor may include TGVs having non-circular cross sections on an outer region (e.g., a bent region) of the S-shaped inductor and may include TGVs having circular cross sections on an inner region (e.g., a straight region) of the S-shaped inductor.

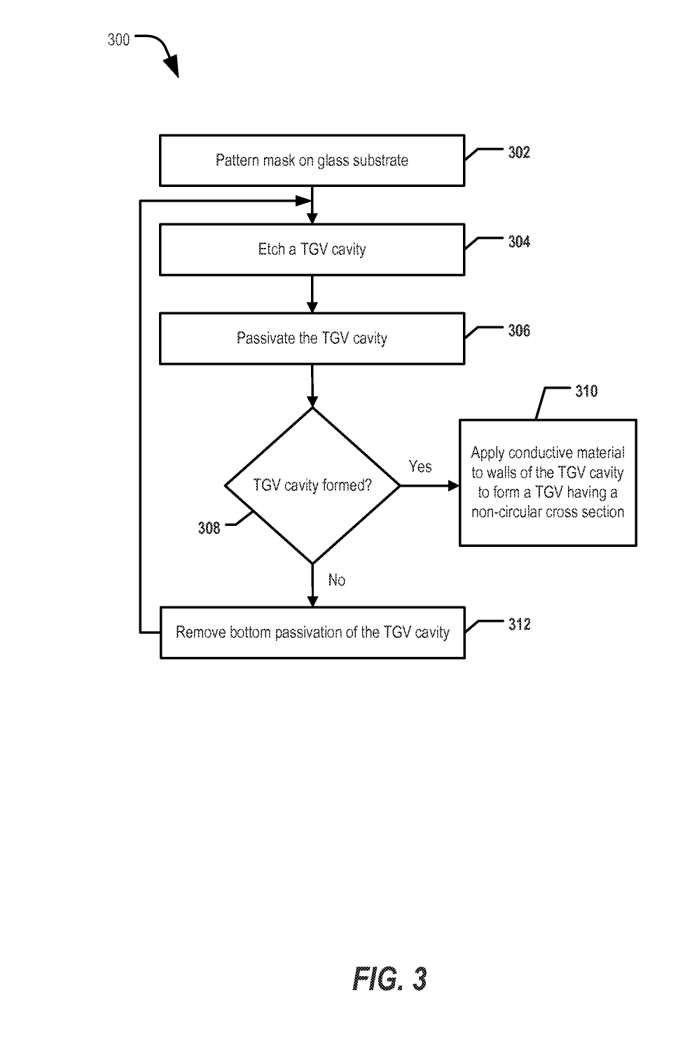

FIG. 3 is a flowchart that illustrates a particular embodiment of a method 300 to manufacture a TGV (e.g. the TGV 106 of FIG. 1, the TGV 208, or the TGV 210 of FIG. 2) having a non-circular cross section. The method 300 includes patterning a mask on a glass substrate (e.g., the glass substrate 102 of FIG. 1 or the glass substrate 202 of FIG. 2), at 302. For example, a TGV hard mask may be deposited on a glass substrate. The TGV hard mask may be a photo resist mask. The TGV hard mask may be patterned to create openings where the TGVs are to be fabricated. The method 300 also includes etching a TGV cavity, at 304. For example, wet etching or vapor etching may be applied to the openings to create a TGV cavity that has a non-circular cross sectional shape. For example, the non-circular cross-sectional shape may be an oval shape, an elliptical shape, a rectangular shape, a concave shape, or any other shape that is useful to provide improved magnetic shielding.

The method 300 further includes passivating the TGV cavity, at 306. For example, a passivation layer (e.g., a layer of SiN or SiC) may be deposited into sidewalls and into the bottom of the TGV cavity. The method 300 further includes determining whether the TGV cavity is complete (e.g., whether the TGV cavity extends through the glass substrate), at 308. When the TGV cavity is not complete, the method 300 further includes removing bottom passivation of the TGV cavity. For example, a passivation layer located at the bottom of the TGV cavity may be removed via a sputter cleaning process. The method 300 may repeat etching the TGV cavity, passivating the TGV cavity, and removing the bottom passivation of the TGV cavity until the TGV cavity is complete. After the TGV cavity is complete (e.g., the TGV cavity extends through the glass substrate), the method 300 further includes applying conductive material to walls of the TGV cavity to form a TGV (e.g., the second TGV 106, the third TGV 208, or the fourth TGV 210) having a non-circular cross section, at 310. For example, a metal layer may be applied to walls of the TGV cavity to form the TGV. Thus, the method 300 may enable a TGV having a non-circular cross section to be manufactured.

After manufacturing of the TGV having a non-circular cross section is complete, other layers or components of a semiconductor device may be implemented using the TGV having a non-circular cross section. For example, an inductor (e.g. the electronic device 100 of FIG. 1) may be formed using the TGV having a non-circular cross section. As another example, a toroidal inductor (e.g., the electronic device 200 of FIG. 2) may be formed using TGVs having a non-circular cross section. It should be understood that a TGV having a non-circular cross section may be formed using other processes. For example, a TGV having a non-circular cross section may be formed using a forming-glass process, laser drilling methods, and discharge methods.

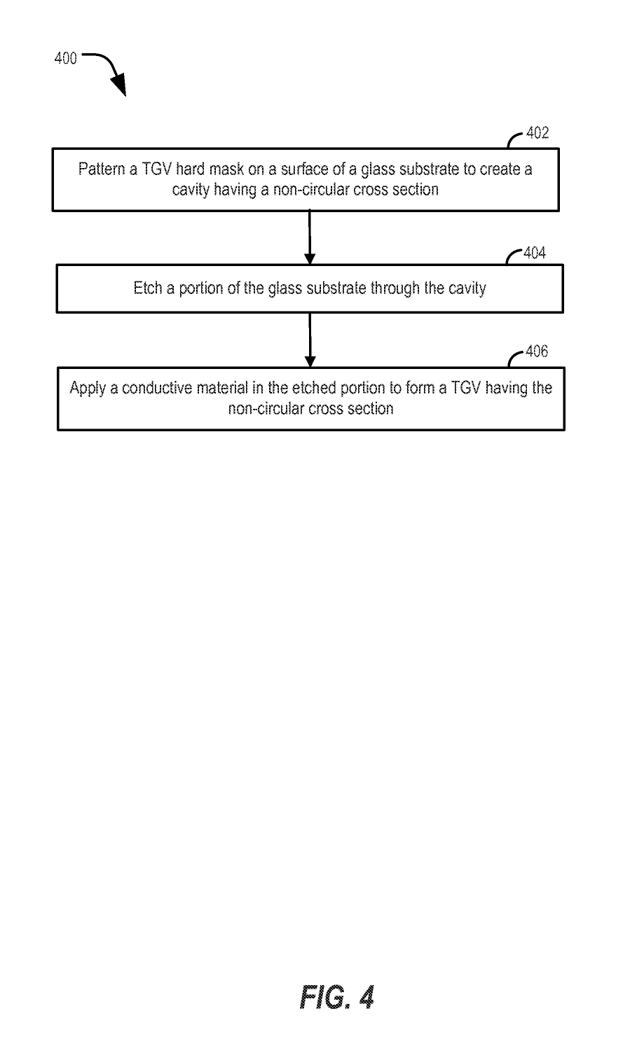

FIG. 4 is a flowchart that illustrates another particular embodiment of a method 400 to manufacture a TGV having a non-circular cross section. The method 400 includes patterning a TGV hard mask on a surface of a glass substrate to create a cavity having a non-circular cross section, at 402. For example, a TGV hard mask may be deposited on a glass substrate, and the TGV hard mask may be patterned to create openings where the TGVs are to be fabricated. The method 400 also includes etching a portion of the glass substrate through the cavity, at 404. For example, wet etching or vapor etching may be applied to the openings to create a TGV cavity that has a non-circular cross sectional shape. The method 400 further includes applying a conductive material in the etched portion to form a TGV having the non-circular cross section, at 406. The TGV is integrated in a device that comprises a structure. The structure comprises a first set of TGVs and a second set of TGVs. The first set of TGVs comprises a first via and the second set of TGVs comprises a second via. The first via has a different cross-sectional shape than the second via. For example, a metal layer may be applied to walls of the TGV cavity to form the TGV. The TGV may be integrated into the electronic device 100 of FIG. 1. Thus, the method 400 may enable a TGV having a non-circular cross section to be manufactured.

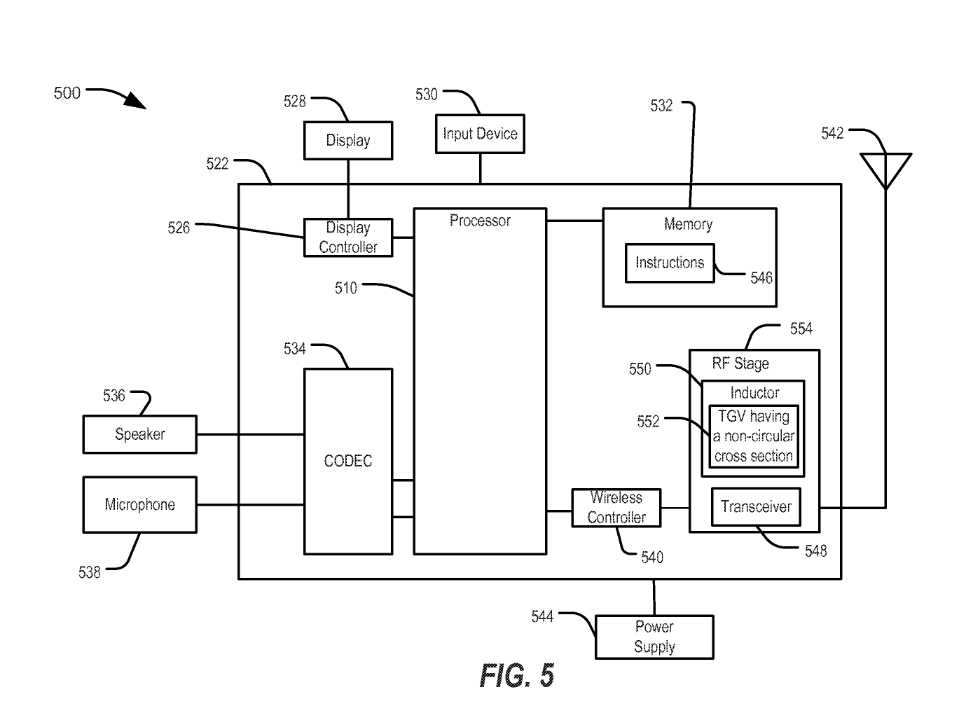

FIG. 5 is a diagram that illustrates a communication device 500 that includes an inductor 550 (e.g., the device 100 of FIG. 1 or the toroidal inductor 200 of FIG. 2) that includes a TGV 552 (e.g., the second TGV 106 of FIG. 1, the third TGV 208, or the fourth TGV 210) having a non-circular cross section. The methods described in FIGS. 3-4, or certain portions thereof, may be used to manufacture the inductor 550.

The communication device 500 includes a processor 510, such as a digital signal processor (DSP), coupled to a memory 532. The memory 532 may be a non-transitory tangible computer-readable and/or processor-readable storage device that stores instructions 546. The instructions 546 may be executable by the processor 510 to perform one or more functions.

FIG. 5 shows that the communication device 500 may also include a display controller 526 that is coupled to the processor 510 and to a display device 528. A coder/decoder (CODEC) 534 can also be coupled to the processor 510. A speaker 536 and a microphone 538 can be coupled to the CODEC 534. FIG. 5 also shows a wireless controller 540 coupled to the processor 510. The wireless controller 540 is in communication with an antenna 542 via a transceiver 548. The transceiver 548 may be located in a radio frequency (RF) stage 554. The wireless controller 540, the transceiver 548, and the antenna 542 may represent a wireless interface that enables wireless communication by the communication device 500. The communication device 500 may include numerous wireless interfaces, where different wireless networks are configured to support different networking technologies or combinations of networking technologies (e.g., Bluetooth low energy, Near-field communication, Wi-Fi, cellular, etc.).

In a particular embodiment, the processor 510, the display controller 526, the memory 532, the CODEC 534, the wireless controller 540, and the transceiver 548 are included in a system-in-package or system-on-chip device 522. In a particular embodiment, an input device 530 and a power supply 544 are coupled to the system-on-chip device 522. Moreover, in a particular embodiment, as illustrated in FIG. 5, the display device 528, the input device 530, the speaker 536, the microphone 538, the antenna 542, and the power supply 544 are external to the system-on-chip device 522. However, each of the display device 528, the input device 530, the speaker 536, the microphone 538, the antenna 542, and the power supply 544 can be coupled to a component of the system-on-chip device 522, such as an interface or a controller.

The RF stage 554 may be implemented, at least in part, using electronic devices (e.g., inductors), such as an illustrative inductor 550. The inductor 550 may include the TGV 552 having a non-circular cross section. For example, the inductor 550 may be the device 100 of FIG. 1, the toroidal inductor 200 of FIG. 2, or any combination thereof. The TGV 552 may represent the second TGV 106 of FIG. 1, or multiple TGVs (e.g., the multiple TGVs of the outer region of the toroidal inductor of FIG. 2). The inductor 550 may be used in circuits (e.g., inductors in one or more components) of the communication device 500 to reduce interference from nearby electromagnetic signals.

In conjunction with the described embodiments, an apparatus may include means for shielding electromagnetic signals. For example, the means for shielding electromagnetic signals may include the second TGV 106 of FIG. 1, the third TGV 208 of FIG. 2, the fourth TGV 210, the TGV 552 of FIG. 5, the toroidal inductor 200 of FIG. 2, a TGV of the inductor 550 of FIG. 5, one or more devices configured to shield electromagnetic signals, or any combination thereof. The means for shielding electromagnetic signals comprises a device with a non-circular cross section. For example, the means for shielding may include the second TGV 106 with the non-circular cross section 114, the third TGV 208 and the fourth TGV 210 that each has a non-circular cross-sectional shape, or the TGV 552.

The apparatus also includes means for providing a conduction channel. For example, the means for providing a conduction channel may include the first TGV 104 of FIG. 1, the first TGV 204 and the second TGV 206 of FIG. 2, one or more components (e.g., a TGV having a circular cross section) of the inductor 550, one or more devices configured to provide a conduction channel, or any combination thereof. The means for providing a conduction channel is connected to the means for shielding electromagnetic signals via a metal trace. For example, a metal trace 108 may connect the first TGV 104 to the second TGV 106. The first TGV 204 may be connected to the third TGV 208 via a first metal trace 212, and the third TGV 208 may be connected to the second TGV 206 via a second metal trace 214. The second TGV 206 may be connected to the fourth TGV 210 via a third metal trace 216.

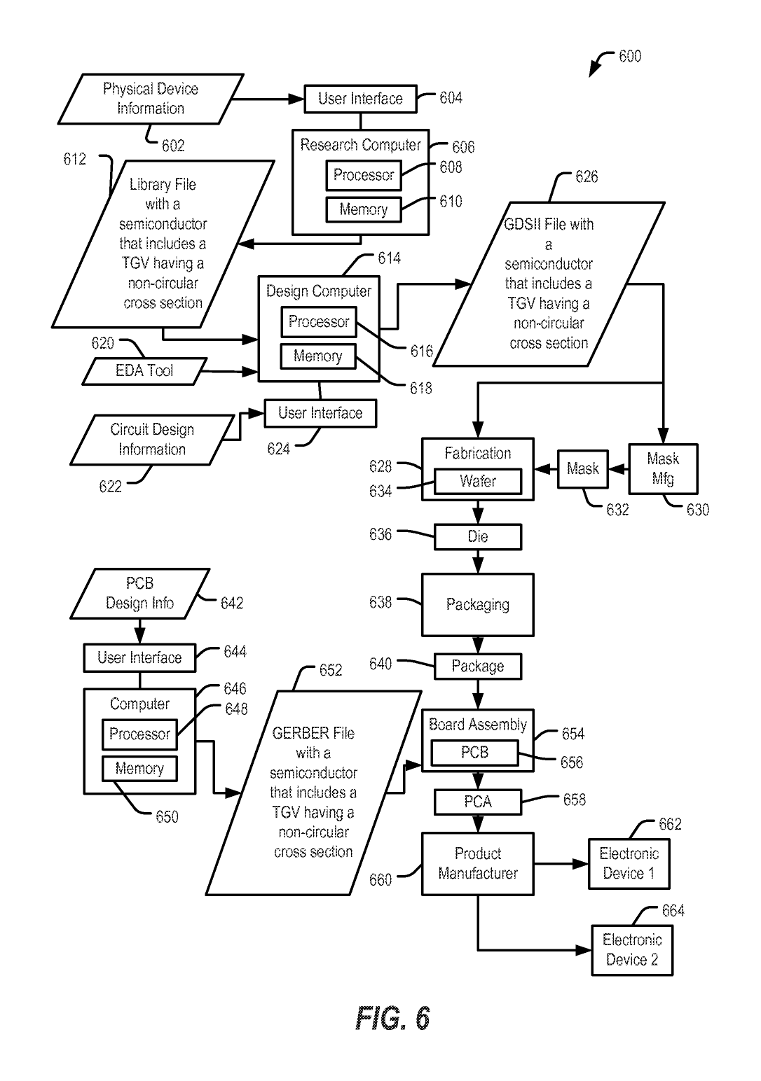

The foregoing disclosed devices and functionalities may be designed and configured into computer files (e.g. RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above. FIG. 6 depicts a particular illustrative embodiment of an electronic device manufacturing process 600.

Physical device information 602 is received at the manufacturing process 600, such as at a research computer 606. The physical device information 602 may include design information representing at least one physical property of a semiconductor device, such as a device that includes the second TGV 106 of FIG. 1, the third TGV 208 of FIG. 2, the fourth TGV 210, or any combination thereof. For example, the physical device information 602 may include physical parameters, material characteristics, and structure information that is entered via a user interface 604 coupled to the research computer 606. The research computer 606 includes a processor 608, such as one or more processing cores, coupled to a computer readable medium such as a memory 610. The memory 610 may store computer readable instructions that are executable to cause the processor 608 to transform the physical device information 602 to comply with a file format and to generate a library file 612.

In a particular embodiment, the library file 612 includes at least one data file including the transformed design information. For example, the library file 612 may include a library of semiconductor devices including a device that includes the second TGV 106, the third TGV 208, the fourth TGV 210, or any combination thereof, that is provided for use with an electronic design automation (EDA) tool 620.

The library file 612 may be used in conjunction with the EDA tool 620 at a design computer 614 including a processor 616, such as one or more processing cores, coupled to a memory 618. The EDA tool 620 may be stored as processor executable instructions at the memory 618 to enable a user of the design computer 614 to design a circuit including the second TGV 106, the third TGV 208, the fourth TGV 210, or any combination thereof, of the library file 612. For example, a user of the design computer 614 may enter circuit design information 622 via a user interface 824 coupled to the design computer 614. The circuit design information 622 may include design information representing at least one physical property of a semiconductor device, such as a device that includes the second TGV 106, the third TGV 208, the fourth TGV 210, or any combination thereof. To illustrate, the circuit design property may include identification of particular circuits and relationships to other elements in a circuit design, positioning information, feature size information, interconnection information, or other information representing a physical property of a semiconductor device.

The design computer 614 may be configured to transform the design information, including the circuit design information 622, to comply with a file format. To illustrate, the file formation may include a database binary file format representing planar geometric shapes, text labels, and other information about a circuit layout in a hierarchical format, such as a Graphic Data System (GDSII) file format. The design computer 614 may be configured to generate a data file including the transformed design information, such as a GDSII file 626 that includes information describing the second TGV 106, the third TGV 208, the fourth TGV 210, or any combination thereof, in addition to other circuits or information. To illustrate, the data file may include information corresponding to a system-on-chip (SOC) that includes the second TGV 106, the third TGV 208, the fourth TGV 210, and that also includes additional electronic circuits and components within the SOC.

The GDSII file 626 may be received at a fabrication process 628 to manufacture the second TGV 106, the third TGV 208, the fourth TGV 210, or any combination thereof, according to transformed information in the GDSII file 626. For example, a device manufacture process may include providing the GDSII file 626 to a mask manufacturer 630 to create one or more masks, such as masks to be used with photolithography processing, illustrated as a representative mask 632. The mask 632 may be used during the fabrication process to generate one or more wafers 634, which may be tested and separated into dies, such as a representative die 636. The die 636 includes a circuit including a device that includes the second TGV 106, the third TGV 208, the fourth TGV 210, or any combination thereof.

The die 636 may be provided to a packaging process 638 where the die 636 is incorporated into a representative package 640. For example, the package 640 may include the single die 636 or multiple dies, such as a system-in-package (SiP) arrangement. The package 640 may be configured to conform to one or more standards or specifications, such as Joint Electron Device Engineering Council (JEDEC) standards.

Information regarding the package 640 may be distributed to various product designers, such as via a component library stored at a computer 646. The computer 646 may include a processor 648, such as one or more processing cores, coupled to a memory 650. A printed circuit board (PCB) tool may be stored as processor executable instructions at the memory 650 to process PCB design information 642 received from a user of the computer 646 via a user interface 644. The PCB design information 642 may include physical positioning information of a packaged semiconductor device on a circuit board, the packaged semiconductor device corresponding to the package 640 including the second TGV 106, the third TGV 208, the fourth TGV 210, or any combination thereof.

The computer 646 may be configured to transform the PCB design information 642 to generate a data file, such as a GERBER file 652 with data that includes physical positioning information of a packaged semiconductor device on a circuit board, as well as layout of electrical connections such as traces and vias, where the packaged semiconductor device corresponds to the package 640 including the second TGV 106, the third TGV 208, the fourth TGV 210, or any combination thereof. In other embodiments, the data file generated by the transformed PCB design information may have a format other than a GERBER format.

The GERBER file 652 may be received at a board assembly process 654 and used to create PCBs, such as a representative PCB 656, manufactured in accordance with the design information stored within the GERBER file 652. For example, the GERBER file 652 may be uploaded to one or more machines to perform various steps of a PCB production process. The PCB 656 may be populated with electronic components including the package 640 to form a representative printed circuit assembly (PCA) 658.

The PCA 658 may be received at a product manufacture process 660 and integrated into one or more electronic devices, such as a first representative electronic device 662 and a second representative electronic device 664. As an illustrative, non-limiting example, the first representative electronic device 662, the second representative electronic device 664, or both, may be selected from the group of a set top box, a music player, a video player, an entertainment unit, a navigation device, a communications device, a personal digital assistant (PDA), a fixed location data unit, and a computer, into which a device that includes the second TGV 106, the third TGV 208, or the fourth TGV 210 is integrated. As another illustrative, non-limiting example, one or more of the electronic devices 662 and 664 may be remote units such as mobile phones, hand-held personal communication systems (PCS) units, portable data units such as personal data assistants, global positioning system (GPS) enabled devices, navigation devices, fixed location data units such as meter reading equipment, or any other device that stores or retrieves data or computer instructions, or any combination thereof. Although FIG. 6 illustrates remote units according to teachings of the disclosure, the disclosure is not limited to these illustrated units. Embodiments of the disclosure may be suitably employed in any device which includes electronic circuitry.

A device that includes the second TGV 106, the third TGV 208, the fourth TGV 210, or any combination thereof, may be fabricated, processed, and incorporated into an electronic device, as described in the illustrative process 600. One or more aspects of the embodiments disclosed with respect to FIGS. 1-5 may be included at various processing stages, such as within the library file 612, the GDSII file 626, and the GERBER file 652, as well as stored at the memory 610 of the research computer 606, the memory 618 of the design computer 614, the memory 650 of the computer 646, the memory of one or more other computers or processors (not shown) used at the various stages, such as at the board assembly process 654, and also incorporated into one or more other physical embodiments such as the mask 632, the die 636, the package 640, the PCA 658, other products such as prototype circuits or devices (not shown), or any combination thereof. Although various representative stages of production from a physical device design to a final product are depicted, in other embodiments fewer stages may be used or additional stages may be included. Similarly, the process 600 may be performed by a single entity or by one or more entities performing various stages of the process 600.

One or more of the disclosed embodiments may be implemented in a system or an apparatus that includes a portable music player, a personal digital assistant (PDA), a mobile location data unit, a mobile phone, a cellular phone, a computer, a tablet, a portable digital video player, or a portable computer. Additionally, the system or the apparatus may include a communications device, a fixed location data unit, a set top box, an entertainment unit, a navigation device, a monitor, a computer monitor, a television, a tuner, a radio, a satellite radio, a music player, a digital music player, a video player, a digital video player, a digital video disc (DVD) player, a desktop computer, any other device that stores or retrieves data or computer instructions, or a combination thereof. As another illustrative, non-limiting example, the system or the apparatus may include remote units, such as global positioning system (GPS) enabled devices, navigation devices, fixed location data units such as meter reading equipment, or any other electronic device. Although one or more of FIGS. 1-6 illustrate systems, apparatuses, and/or methods according to the teachings of the disclosure, the disclosure is not limited to these illustrated systems, apparatuses, and/or methods. Embodiments of the disclosure may be employed in any device that includes circuitry.

It should be understood that any reference to an element herein using a designation such as “first.” “second,” and so forth does not generally limit the quantity or order of those elements. Rather, these designations may be used herein as a convenient method of distinguishing between two or more elements or instances of an element. Thus, a reference to first and second elements does not mean that only two elements may be employed or that the first element must precede the second element in some manner. Also, unless stated otherwise a set of elements may comprise one or more elements.

As used herein, the term “determining” encompasses a wide variety of actions. For example, “determining” may include calculating, computing, processing, deriving, investigating, looking up (e.g., looking up in a table, a database or another data structure), ascertaining and the like. Also, “determining” may include receiving (e.g., receiving information), accessing (e.g. accessing data in a memory) and the like. Also, “determining” may include resolving, selecting, choosing, establishing and the like.

As used herein, a phrase referring to “at least one of” a list of items refers to any combination of those items, including single members. As an example, “at least one of: a, b, or c” is intended to cover: a, b, c, a-b, a-c, b-c, and a-b-c.

Various illustrative components, blocks, configurations, modules, circuits, and steps have been described above generally in terms of their functionality. Whether such functionality is implemented as hardware or processor executable instructions depends upon the particular application and design constraints imposed on the overall system. Additionally, the various operations of methods described above (e.g., any operation illustrated in FIGS. 3-4) may be performed by any suitable means capable of performing the operations, such as various hardware and/or software component(s), circuits, and/or module(s). Skilled artisans may implement the described functionality in varying ways for each particular application, but such implementation decisions should not be interpreted as causing a departure from the scope of the present disclosure.

Those of skill in the art would further appreciate that the various illustrative logical blocks, configurations, modules, circuits, and algorithm steps described in connection with the present disclosure may be implemented or performed with a general purpose processor, a digital signal processor (DSP), an application specific integrated circuit (ASIC), a field programmable gate array (FPGA), a programmable logic device (PLD), discrete gate or transistor logic, discrete hardware components (e.g. electronic hardware), computer software executed by a processor, or any combination thereof designed to perform the functions described herein. A general purpose processor may be a microprocessor, but in the alternative, the processor may be any commercially available processor, controller, microcontroller or state machine. A processor may also be implemented as a combination of computing devices, e.g., a combination of a DSP and a microprocessor, a plurality of microprocessors, one or more microprocessors in conjunction with a DSP core, or any other such configuration.

In one or more aspects, the functions described may be implemented in hardware, software, firmware, or any combination thereof. If implemented in software, the functions may be stored as one or more instructions or code on a computer-readable medium. Computer-readable media includes computer readable storage media and communication media including any medium that facilitates transfer of computer program data from one place to another. A storage media may be any available media that can be accessed by a computer. By way of example, and not limitation, such computer readable storage media can include random access memory (RAM), read-only memory (ROM), programmable read-only memory (PROM), erasable PROM (EPROM), electrically erasable PROM (EEPROM), register(s), hard disk, a removable disk, a compact disc read-only memory (CD-ROM), other optical disk storage, magnetic disk storage, magnetic storage devices, or any other medium that can be used to store program code in the form of instructions or data and that can be accessed by a computer. In the alternative, the computer-readable media (e.g., a storage medium) may be integral to the processor. The processor and the storage medium may reside in an application-specific integrated circuit (ASIC). The ASIC may reside in a computing device or a user terminal. In the alternative, the processor and the storage medium may reside as discrete components in a computing device or user terminal.

Also, any connection is properly termed a computer-readable medium. For example, if software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), and floppy disk where disks usually reproduce data magnetically, while discs reproduce data optically with lasers. Thus, in some aspects computer readable medium may include a non-transitory computer readable medium (e.g., tangible media). Combinations of the above should also be included within the scope of computer-readable media.

The methods disclosed herein include one or more steps or actions. The method steps and/or actions may be interchanged with one another without departing from the scope of the claims. In other words, unless a specific order of steps or actions is specified, the order and/or use of specific steps and/or actions may be modified without departing from the scope of the disclosure.

Certain aspects may include a computer program product for performing the operations presented herein. For example, a computer program product may include a computer-readable storage medium having instructions stored (and/or encoded) thereon, the instructions being executable by one or more processors to perform the operations described herein. The computer program product may include packaging material.

Further, it should be appreciated that modules and/or other appropriate means for performing the methods and techniques described herein can be downloaded and/or otherwise obtained by a user terminal and/or base station as applicable. Alternatively, various methods described herein can be provided via storage means (e.g. RAM, ROM, or a physical storage medium such as a compact disc (CD)). Moreover, any other suitable technique for providing the methods and techniques described herein can be utilized. It is to be understood that the scope of the disclosure is not limited to the precise configuration and components illustrated above.

The previous description of the disclosed embodiments is provided to enable a person skilled in the art to make or use the disclosed embodiments. While the foregoing is directed to aspects of the present disclosure, other aspects of the disclosure may be devised without departing from the basic scope thereof, and the scope is determined by the claims that follow. Various modifications, changes and variations may be made in the arrangement, operation, and details of the embodiments described herein without departing from the scope of the disclosure or the claims. Thus, the present disclosure is not intended to be limited to the embodiments herein but is to be accorded the widest scope possible consistent with the principles and novel features as defined by the following claims and equivalents thereof.

What is claimed is:

1. An electronic device comprising:
a structure, the structure comprising a first set of through glass vias (TGVs) and a second set of TGVs, the first set of TGVs comprising a first via and the second set of TGVs comprising a second via, wherein the first via has a different cross-sectional shape than the second via.

2. The electronic device of claim 1, wherein the first via has a circular cross section.

3. The electronic device of claim 1, wherein the second via has a non-circular cross section.

4. The electronic device of claim 1, wherein the structure is a toroidal inductor structure, wherein the first set of TGVs corresponds to an inner region of the toroidal inductor structure, and wherein the second set of TGVs corresponds to an outer region of the toroidal inductor structure.

5. The electronic device of claim 4, wherein a Q factor of the inductor structure is at least partially based on a shielding capability of the second set of TGVs.

6. The electronic device of claim 1, wherein the first via has a circular cross-sectional shape, and wherein the second via has a non-circular cross-sectional shape.

7. The electronic device of claim 1, wherein the second via has a greater width than the first via.

8. The electronic device of claim 1, wherein the structure is a half bent solenoid inductor structure, wherein the first set of TGVs corresponds to an inner region of the half bent solenoid inductor structure, and wherein the second set of TGVs corresponds to an outer region of the half bent solenoid inductor structure.

9. The electronic device of claim 1, wherein the structure is an S-shaped inductor structure, wherein the first set of TGVs corresponds to a first region of the S-shaped inductor structure, and wherein the second set of TGVs corresponds to a second region of the S-shaped inductor structure.

10. The electronic device of claim 1, wherein the second via has an oval cross section.

11. The electronic device of claim 1, wherein the second via has an elliptical cross section.

12. The electronic device of claim 1, wherein the second via has a rectangular cross section.

13. The electronic device of claim 1, wherein the second via has a concave cross section.

14. The electronic device of claim 1, wherein the TGV is integrated in at least one semiconductor die.

15. The electronic device of claim 1, further comprising a device selected from the group consisting of a set top box, a music player, a video player, an entertainment unit, a navigation device, a communications device, a personal digital assistant (PDA), a fixed location data unit, and a computer, into which the electronic device is integrated.

16. A method comprising:
patterning a through glass via (TGV) hard mask on a surface of a glass substrate to create a cavity having a non-circular cross section;
etching a portion of the glass substrate through the cavity; and
applying a conductive material in the etched portion to form a TGV, wherein the TGV is integrated in a device that comprises a structure, the structure comprising a first set of TGVs and a second set of TGVs, the first set of TGVs comprising a first via and the second set of TGVs comprising a second via, wherein the first via has a different cross-sectional shape than the second via.

17. The method of claim 16, wherein the second via has a non-circular cross section.

18. The method of claim 16, wherein the first via has a circular cross section.

19. The method of claim 16, wherein the structure is a toroidal inductor structure, wherein the first set of TGVs corresponds to an inner region of the toroidal inductor structure, and wherein the second set of TGVs corresponds to an outer region of the toroidal inductor structure.

20. The method of claim 16, wherein the second via has a greater width than the first via.

21. The method of claim 16, wherein the second via has an elliptical cross section.

22. The method of claim 16, wherein patterning, etching, and applying are controlled by a processor.

23. An electronic device comprising:
means for shielding electromagnetic signals, wherein the means for shielding electromagnetic signals comprises a device with a non-circular cross section; and
means for providing a conduction channel, wherein the means for providing a conduction channel is connected to the means for shielding electromagnetic signals via a metal trace.

24. The electronic device of claim 23, further comprising a device selected from the group consisting of a set top box, a music player, a video player, an entertainment unit, a navigation device, a communications device, a personal digital assistant (PDA), a fixed location data unit, and a computer, into which the device is integrated.

25. A non-transitory computer-readable storage medium storing instructions executable by a computer to perform operations comprising:
patterning a through glass via (TGV) hard mask on a surface of a glass substrate to create a cavity having a non-circular cross section;
etching a portion of the glass substrate through the cavity; and
applying a conductive material in the etched portion to form a TGV having the non-circular cross section, wherein the TGV is integrated in a device that comprises a structure, the structure comprising a first set of TGVs and a second set of TGVs, the first set of TGVs comprising a first via and the second set of TGVs comprising a second via, wherein the first via has a different cross-sectional shape than the second via.

26. The computer-readable storage medium of claim 25, wherein the TGV is included in an outer region of a toroidal inductor.

27. A method comprising:
receiving design information comprising physical positioning information of a packaged semiconductor device on a circuit board, the packaged semiconductor device comprising:
a structure comprising a first set of through glass vias (TGVs) and a second set of TGVs, the first set of TGVs comprising a first via and the second set of TGVs comprising a second via, wherein the first via has a different cross-sectional shape than the second via; and
transforming the design information to generate a data file.

28. The method of claim 27, wherein the TGV is included in a toroidal inductor that is a component of the package semiconductor device.

29. The method of claim 27, wherein the data file has a GERBER format.

30. The method of claim 27, wherein the data file has a GDSII format.
